(19) United States
(12) Patent Application Publication
(10) Pub. No.: US 2008/0184802 A1
(43) Pub. Date: Aug. 7, 2008

(54) Mount structure for sensor device

(75) Inventor: Yoshihisa Sato, Nagoya-city (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/068,057

(22) Filed: Feb. 1, 2008

(30) Foreign Application Priority Data
Feb. 5, 2007 (JP) 2007-25943

(51) Int. Cl. G12B 9/08; G01D 11/30; H05K 7/14; G01S 15/93; G12B 9/02; G01D 11/24

(52) U.S. Cl. 73/632; 73/866.5; 248/27.1; 361/807

(57) ABSTRACT

A mount structure for a mobile unit includes a wall member, a sensor device, and a color film. The wall member is provided to the mobile unit, and the wall member has a through hole and an outer surface. The sensor device is mounted on the wall member via the through hole such that a sensing element of the sensor device is able to perform sensing. The sensor device is coupled to the wall member in a state, where the sensor device has a portion that is generally flush with the outer surface of the wall member, and that is provided inside the through hole. The color film is adhered to an entire surface of the outer surface of the wall member, and the entire surface has an opening of the through hole. The sensor device contacts the color film.

### CROSS REFERENCE TO RELATED APPLICATION

This application is based on and incorporates herein by reference Japanese Patent Application No. 2007-25943 filed on Feb. 5, 2007.

### BACKGROUND OF THE INVENTION

1. Field of the Invention

The present invention relates to a mount structure for a sensor device, which structure mounts the sensor device on a wall member of a mobile unit, such as a vehicle bumper.

2. Description of Related Art

Conventionally, there is known a mount structure for a sensor device, in which structure a wall member (e.g., a vehicle bumper) of a mobile unit has a through hole, and the sensor device is mounted on the wall member through the through hole such that a sensing element can sense an object (see, for example, JP-A-2004-264264).

In JP-A-2004-264264, a bumper (wall member) has a mounting hole (through hole) that extends through the bumper from one surface to an opposite surface, and a sensor device has a housing (enclosure) that receives an ultrasonic transducer (sensing element). The sensor device is fixed (i.e., coupled) to the bumper in a mounting state, where the ultrasonic transducer is exposed to the exterior through the mounting hole.

In a case, where the sensor device is exposed to the exterior of the mobile unit through the through hole of the wall member similarly to the sensor device described in JP-A-2004-264264, the following process is required in order to improve design. That is, in an assembly state, where the sensor device is assembled to the wall member, the exposed surface of the sensor device is painted or decorated together with the wall member. In the decoration process, the paint is dried at high temperature in order to improve the productivity and quality (for example, for limiting the attachment of objects to the surface). Thus, the sensor device is held in the high temperature atmosphere, and thereby the sensor device may be damaged. For example, adhesive for fixing the sensing element may be influenced by the heat, and as a result, the sensing element may be misaligned or detached. Also, a processing circuit of the sensing element may be influenced by the heat, and as a result, the processing circuit may malfunction.

### SUMMARY OF THE INVENTION

The present invention is made in view of the above disadvantages. Thus, it is an objective of the present invention to address at least one of the above disadvantages.

To achieve the objective of the present invention, there is provided a mount structure for a mobile unit, the mount structure including a wall member, a sensor device, and a color film. The wall member is provided to the mobile unit, and the wall member has a through hole and an outer surface. The sensor device is mounted on the wall member via the through hole such that a sensing element of the sensor device is able to perform sensing. The sensor device is coupled to the wall member in a state, where the sensor device has a portion that is generally flush with the outer surface of the wall member, and that is provided inside the through hole. The color film is adhered to an entire surface of the outer surface of the wall member, and the entire surface has an opening of the through hole. The sensor device contacts the color film.

To achieve the objective of the present invention, there is also provided a mount structure for a mobile unit, the mount structure including a sensor device and a color film. The sensor device is mounted on a wall member of the mobile unit via a through hole of the wall member such that a sensing element of the sensor device is able to perform sensing. The sensor device is coupled to the wall member in a state, where the sensor device has a portion that is generally flush with an outer surface of the wall member, and that is provided inside the through hole. The color film is adhered to an entire surface of the outer surface of the wall member. The entire surface has an opening of the through hole. The sensor device contacts the color film.

### BRIEF DESCRIPTION OF THE DRAWINGS

The invention, together with additional objectives, features and advantages thereof, will be best understood from the following description, the appended claims and the accompanying drawings in which:

FIG. 1 is a perspective view showing a periphery of a rear bumper of a vehicle, to which a mount structure for a sensor device according to embodiments of the present invention is applied;

FIG. 2 is a cross-sectional view schematically showing a mount structure for a sensor device according to a first embodiment of the present invention;

FIG. 3 is a plan view of the mount structure in FIG. 2 observed from an exterior of the vehicle;

FIG. 4 is a cross-sectional view schematically showing a mount structure for a sensor device according to a second embodiment of the present invention;

FIG. 5 is a plan view of the mount structure shown in FIG. 4 observed from the exterior of the vehicle;

FIG. 6 is a plan view showing a modified embodiment of the second embodiment;

FIG. 7 is a cross-sectional view showing another modified embodiment of the second embodiment;

FIG. 8 is a cross-sectional view showing still another modified embodiment of the second embodiment;

FIG. 9 is a cross-sectional view showing further still another modified embodiment of the second embodiment; and

FIG. 10 is a drawing showing anther modified embodiment.

### DETAILED DESCRIPTION OF PREFERRED EMBODIMENTS

Embodiments of the present invention will be described with reference to accompanying drawings. In each of the embodiments, there is described a mount structure that mounts a sensor device on a mobile unit. Particularly, the mobile unit is a vehicle, and the sensor device has an ultrasonic element serving as a sensing element.

### First Embodiment

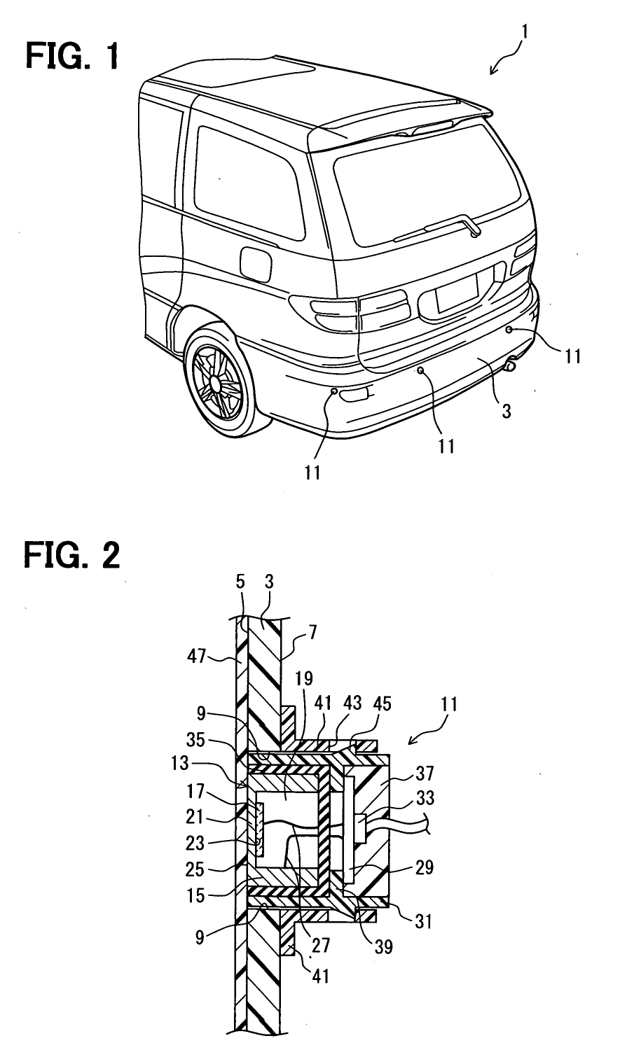

A sensor device is designed to detect an obstacle around a vehicle, and is mounted either on a front side of a vehicle, on a rear side of the vehicle, or on four corners of the vehicle on bumpers. In the present embodiment, as shown in FIG. 1, sensor devices 11 are mounted on four positions of a vehicle 1, typically, on opposite corners of a rear bumper 3 and on two positions between the corners.

As shown in FIG. 2, the sensor device 11 includes an ultrasonic transducer 13 (i.e., a microphone) as a main part. The ultrasonic transducer 13 has a housing 15 and a piezoelectric element 17, which is received by the housing 15. The housing 15 corresponds to an enclosure of the present invention, and is typically made of an electrically conductive member to have a hollow cylinder having a bottom. The electrically conductive member may be aluminum, for example. Alternatively, the housing 15 may be made of a resin material and has an metallized inner surface. The housing 15 has an inner space 19 as shown in FIG. 2, and the housing 15 has a bottom surface portion 21 that has an inner surface 23 adhered with the piezoelectric element 17. Due to the above configuration, the bottom surface portion 21 has an outer surface (an opposite face of the bottom surface portion 21 opposite the inner surface 23) that serves as a vibration plane 25 of the ultrasonic transducer 13.

The piezoelectric element 17 corresponds to a sensing element of the present invention, and is made by sintering piezoelectric ceramics (e.g., PZT, barium titanate). The piezoelectric element 17 has a bonding surface and an opposite surface. The bonding surface is bonded with the housing 15, and the opposite surface is provided on a side of the piezoelectric element 17 opposite to the bonding surface. Electrodes (not shown) are provided on the bonding surface and on the opposite surface. A lead 27 has an end electrically connected with the electrode (not shown) on the opposite surface of the piezoelectric element 17, and another lead 17 has an end electrically connected with an inner surface of the housing 15. Then, the other ends of the leads 27 are taken out of the housing 15. Due to the above structure, an alternating current signal can be applied to both the ends of the piezoelectric element 17 through the leads 27, and thereby the application of the alternating current signal drives the piezoelectric element 17. Thus, the vibration plane 25 of the ultrasonic transducer 13 can be vibrated. Note that, after the connection (soldering) of the leads 27 has been completed, the inner space 19 of the housing 15 is filled with vibration absorber (not shown) to surround the piezoelectric element 17 except for a surface that faces the bottom surface portion 21. The vibration absorber may be made of an elastic body, which is elastic, such as silicone or polyurethane. As a result, vibration by the piezoelectric element 17 is limited from transmitting to other part other than the bottom surface portion 21 of the housing 15.

The above ultrasonic transducer 13 is assembled in a case 31 with a circuit board 29 to constitute the sensor device 11. Typically, the case 31 is made of an electrically insulating material, such as a resin.

The circuit board 29 is electrically connected with the piezoelectric element 17 via the lead 27, and outputs driving signal for vibrating the piezoelectric element 17 to generate ultrasonic waves. Also, the circuit board 29 has a circuit that processes a voltage signal generated by piezoelectric effect when the ultrasonic wave is transmitted to the piezoelectric element 17 and thereby the piezoelectric element 17 has strain. Also, the circuit board 29 is connected with a controller (not shown) via a connector 33, and the controller executes an obstacle detection at a rear of the vehicle or a corner of the vehicle.

The case 31 accommodates a vibration control member 35 for limiting the transmission of unwanted vibration from the ultrasonic transducer 13 to the case 31. The vibration control member 35 is made of, for example, a silicone rubber, and is provided around the ultrasonic transducer 13. More specifically, the vibration control member 35 is provided at a region around the ultrasonic transducer 13 other than the vibration plane 25. Also, a sealing member 37 is admitted to a side of the circuit board 29 opposite to the ultrasonic transducer 13 in order to seal the case 31. The sealing member 37 is typically made of a silicone resin.

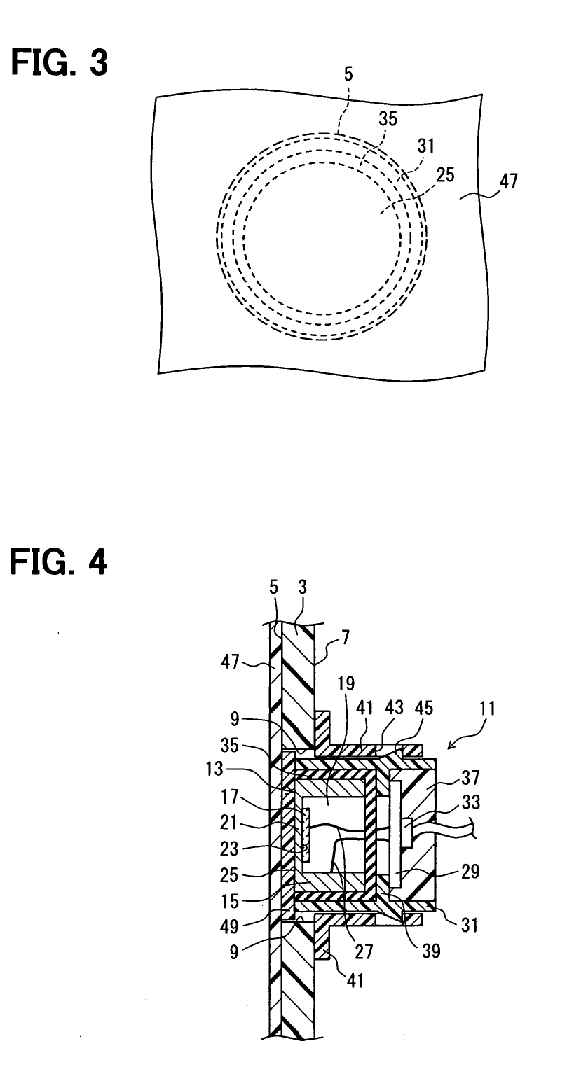

The case 31 has a hollow cylindrical shape, for example, and has a stopper 39 somewhere in the hollow cylinder (e.g., in a middle of the hollow cylinder). The ultrasonic transducer 13 that is adhered with the vibration control member 35 is received by the case 31 through one opening of the case 31, and the stopper 39 secures the ultrasonic transducer 13. Also, the circuit board 29 is received by the case 31 through the other opening of the case 31, and the stopper 39 secures the circuit board 29. In a state, where the ultrasonic transducer 13 is assembled to the case 31, an open end of the case 31 and the vibration plane 25 of the ultrasonic transducer 13 are arranged to be generally flush with each other as shown in FIG. 2. As a result, outline shapes of the vibration plane 25 and the case 31 are generally concentrically arranged relative to each other as shown in FIG. 3. Note that, in the present embodiment, in addition to the above configuration, an end portion of the vibration control member 35 is generally flush with the open end of the case 31 and the vibration plane 25 of the ultrasonic transducer 13, and outline shapes of the above three components are concentrically arranged relative to each other.

The bumper 3 has an outer surface 5 and an inner surface 7. The outer surface 5 faces an exterior of the vehicle, and the inner surface 7 is positioned on a side of the bumper 3 opposite to the outer surface 5 as shown in FIG. 2. Also, the bumper 3 has a through hole 9 that extends through the bumper 3 from the outer surface 5 to the inner surface 7. The sensor device 11 is fixed (coupled) to the bumper 3 in a state, where a part of the sensor device 11 is provided inside the through hole 9 as shown in FIG. 2 and FIG. 3 such that the sensor device 11 is able to perform sensing through the through hole 9. In other words, the sensor device 11 is provided in the above manner such that the sensor device 11 can directly transmit and receive the ultrasonic wave without the bumper 3 to sense an object. In the above fixed state, the outer surface 5 of the bumper 3 is generally flush with the vibration plane 25 of the ultrasonic transducer 13.

In the present embodiment, a holder 41 for securing a sensor device is fixed to the inner surface 7 of the bumper 3, and the holder 41 has an engagement hole 43. Also, a projection 45 is provided at an outer peripheral surface of the case 31 to correspond to the engagement hole 43. In a state, where the vibration plane 25 of the ultrasonic transducer 13 is generally flush with the outer surface 5 of the bumper 3, the projection 45 is engaged with the engagement hole 43 such that the holder 41 secures the sensor device 11 to the bumper 3. Note that, in the present embodiment, as described above, the vibration plane 25 of the ultrasonic transducer 13, the end portion of the case 31, and the end portion of the vibration control member 35 are generally flush with each other, and thereby are generally flush with the outer surface 5 of the bumper 3. Also, as shown in FIG. 3, the vibration plane 25 of the ultrasonic transducer 13, the end portion of the case 31, and the end portion of the vibration control member 35 have the outline shapes that are concentrically arranged relative to the shape of the opening at the outer surface 5 of the bumper 3 (i.e., relative to a hole shape of the through hole 9) as shown in FIG. 3. Note that, in the present embodiment, based on an allowance in assembly and an error in manufacturing, there is formed a slight clearance between (a) a wall face of the through hole 9 and (b) a portion of the sensor device 11 provided inside the through hole 9. In other words, the slight clearance is formed between the bumper 3 and the portion of the sensor device 11 provided inside the through hole 9. In consideration of design, it is better when the clearance is smaller, and alternatively, the clearance may be omitted.

In a state as above, where the sensor device 11 is mounted on the bumper 3 that has the through hole 9, a color film 47 is adhered to an entire surface of the outer surface 5 of the bumper 3 in the present embodiment. As above, the outer surface 5 of the bumper 3 has the opening of through hole 9 and the color film 47 is colored. Also, the color film 47 is also adhered to the end face of the sensor device 11, which end face is generally flush with the outer surface of the bumper 3. The end face of the sensor device 11 includes the vibration plane 25 of the ultrasonic transducer 13, the end portion of the case 31, and the end portion of the vibration control member 35.

The color film 47 serves as a decorating member that covers the sensor device 11 and a boundary between the bumper 3 and the sensor device 11 such that the sensor device 11 and the boundary are less visible or less remarkable from the exterior of the vehicle at a visible range. As a result, the color film 47 may be transparent or opaque provided that the color film 47 is colored. However, from a view point of making the sensor device 11 less visible, the color film 47 may be opaque, for example. Typically, the degree of transparency of the color film 47 can be selected as required in consideration of matching with a periphery of the bumper 3 (e.g., a body) or of the design. Thus, harmony in design between the bumper 3 and a body of the vehicle may be considered. Also, the color film 47 may be made of any film (e.g., sheet, membrane) provided that the film is adhered and fixed to the outer surface 5 of the bumper 3 without thermally damaging the sensor device 11, also provided that the film allows the sensor device 11 to sense through the color film 47. Also, a well-known adhesive may be employed as the component. The adhesive may be moisture cured type or UV cured type that do not require a heat treatment at a high temperature. Preferably, the adhesive may have a flexibility to trace the outer surface 5 of the bumper 3.

In the present embodiment, as an example, a coating film and an adhesive layer are formed on a base (e.g., carrier film) that is releasable from the coating film and the adhesive layer. Then, when the coating film and the adhesive layer are adhered to the bumper 3, the base is removed such that the coating film and the adhesive layer constitute the color film 47. In the manufacturing process of the above color film 47, coating (e.g., urethane resin) is applied on one surface of the base, and then it is dried to make the coating film. Thus, the coating at high temperature ends at this point. The coating film may have a single layer or multiple layers. In the present embodiment, a clear membrane, a ground membrane, and a surface membrane are formed in this order from the base side. The clear membrane is transparent and serves as protection, and the surface membrane has a certain color to match with the body. Then, after the adhesive layer has been formed on the coating film, the adhesive layer is made to serve as the bonding surface that is adhered to the entire surface of the outer surface 5 of the bumper 3. At the time, the sensor device 11 is already mounted on the bumper 3. Then, the base is removed. As above, the color film 47, which is made of the coating film and the adhesive layer, is adhered to the entire surface of the outer surface 5 of the bumper 3 to constitute the mount structure for the sensor device 11. Note that, the base may alternatively remain bonded with the coating film and the adhesive layer such that the base becomes a part of the color film 47. For example, JP-A-2006-212822 describes the detail of the color film 47 and the method for adhering the color film 47. Alternatively, the color film 47 may be first adhered to the outer surface 5 of the bumper 3, and then the sensor device 11 may be mounted on the bumper 3 to constitute the similar mount structure to the above.

In the mount structure for the sensor device 11 according to the present embodiment, the coating is not applied in a state, where the sensor device 11 is mounted on the bumper 3 that has the through hole 9. However, decoration is made by adhering and fixing the color film 47 to the bumper 3 without heat treatment at high temperature. As a result, in the decoration, the sensor device 11 is limited from thermally damaged. Specifically, the adhesive that fixes the piezoelectric element 17 is limited from being softened, and thereby the piezoelectric element 17 is limited from being misaligned or detached. Also, the circuit board 29 is limited from malfunctioning.

Also, because the color film 47 is adhered to the entire surface of the outer surface 5 of the bumper 3, the sensor device 11 and the boundary between the sensor device 11 and the bumper 3 can be made less visible or less remarkable from the exterior or the vehicle. Also, because the color film 47 is adhered to the entire surface of the outer surface 5 of the bumper 3, the outer surface 5 of the bumper 3 has a designed surface that is seamless. Further, the sensor device 11 is fixed such that the end face of the sensor device 11, which is arranged in the through hole 9, is generally flush with the outer surface 5 of the bumper 3, and the end face is also adhered to or contact the color film 47. The end face of the sensor device 11 typically faces toward the exterior of the vehicle and includes the vibration plane 25 of the ultrasonic transducer 13, the end portion of the vibration control member 35, and the end portion of the case 31. As a result, because there is no step (no difference in level) among the outer surface 5 of the bumper 3 and the end face of the sensor device 11, the color film 47 is limited from having a projection or a recess thereon. As above, the sensor device 11 is limited from being damaged and also at the same time, the design is improved.

Also, in a case of a decoration by a conventional coating, masking is necessarily made in advance in order to limit the coating from being applied to a connector (or terminal) of the sensor device 11, and thereby in order to limit the failure in conductivity. In contrast, in the mount structure for the sensor device 11 according to the present embodiment, the above masking is not required, and thereby steps in the decoration process can be reduced.

Also, a conventional technique suggests that a sensor device is fixed to an inner surface of a bumper, which does not have the through hole 9, in order to improve the design. For example, the sensor device may be fixed to an inner surface of a wall member. The above conventional technique may be called an invisible sonar. However, in the above conventional configuration, because the ultrasonic vibration is transmitted through the bumper, physical properties of the component material of the bumper or thickness of the bumper may influence the sensing ability. In the above case, typically, the specification of the bumper cannot be selected flexibly to correspond to the property of the sensor (e.g., to the sensitivity of the sensor) because the specification of the bumper is predetermined based on a model of the vehicle or on a manufacturer. In contrast, in the mount structure of the sensor device 11 according to the present embodiment, the ultrasonic vibration is transmitted between the piezoelectric element 17 and the exterior of the vehicle via the color film 47 and via the bottom surface portion 21 of the housing 15. Because the ultrasonic vibration is not transmitted via the bumper 3 as the conventional technique, the sensor device 11 is not exposed to the exterior of the vehicle, and still the sensing ability is limited from being influenced by physical properties of the component material of the bumper 3 or thickness of the bumper 3.

Also, the present embodiment describes an example, in which the color film 47 is adhered to the outer surface 5 of the bumper 3 in a state, where the sensor device 11 is mounted on the bumper 3. Alternatively, after the color film 47 has been adhered to the outer surface 5 of the bumper 3, the sensor device 11 may be mounted on the bumper 3 to provide the mount structure as above. Note that, sensibility adjustment of the sensor device 11 may be preferably performed in a state, where the color film 47 is adhered to the bumper 3. This is because the sensitivity of the sensor device 11 may deteriorate if the color film 47 is adhered to the sensor device 11 after the sensibility adjustment has been made. In the present embodiment, the sensibility adjustment of the sensor device 11 is performed in a state the color film 47 is adhered to the bumper 3.

### Second Embodiment

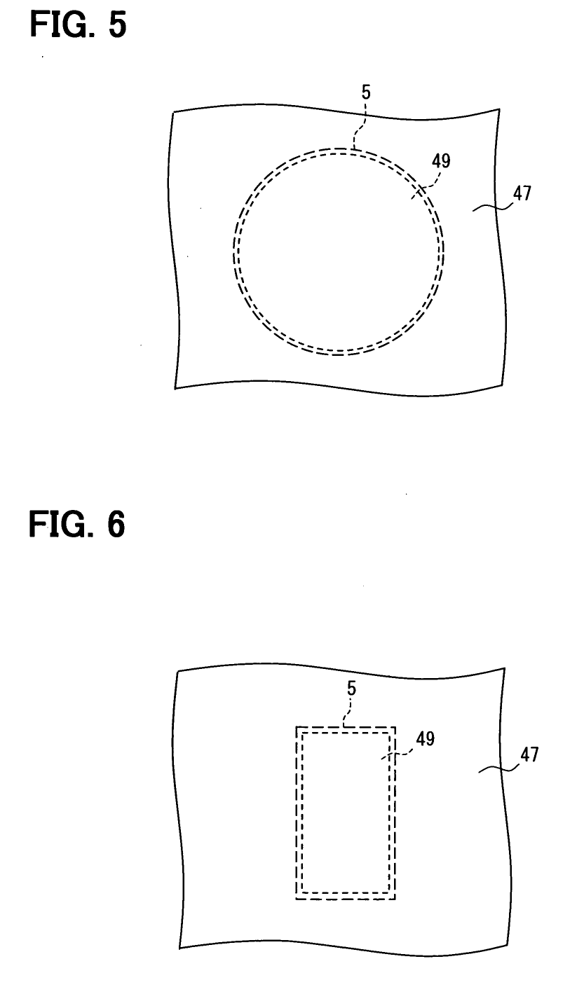

The second embodiment of the present invention will be described with reference to FIG. 4 and FIG. 5.

A mount structure for a sensor device according to the second embodiment has similar components and structures similar to those of the first embodiment. Thus, explanation of the similar components and structures is omitted and parts different from the first embodiment will be mainly described. Note that the similar components similar to those described in the first embodiment are indicated by the same numerals.

In a structure, where a piezoelectric element senses through a bumper (e.g., invisible sonar), the bumper may influence the sensing ability. In the first embodiment, the vibration plane 25 of the ultrasonic transducer 13 directly contacts the color film 47 in order to limit the influence by the bumper 3 on the sensitivity and to improve the design. In practice, the color film 47 is focusing more on improving the design. Thus, in the present embodiment, as shown in FIG. 4, the vibration plane 25 of the ultrasonic transducer 13 is not in direct contact with the color film 47, but the vibration plane 25 contacts the color film 47 through an adjustment member 49. In other words, the color film 47 maintains a good appearance observed from the exterior of the vehicle, and still the adjustment member 49 improves the sensing property (e.g., the sensitivity) in the second embodiment.

The adjustment member 49 is provided between the color film 47 and the housing 15 of the ultrasonic transducer 13 to serve as a part of the transmission path of the ultrasonic vibration such that sensing property can be improved. The color film 47 covers the adjustment member 49 in a state, where a part of the adjustment member 49 is provided inside the through hole 9 of the bumper 3 such that the adjustment member 49 contacts both the vibration plane 25 of the ultrasonic transducer 13 and the color film 47. Also, in order to improve the design, the adjustment member 49 has an opposite surface that is generally flush with the outer surface 5 of the bumper 3 in a state, where the sensor device 11 and the adjustment member 49 are mounted on the bumper 3. The opposite surface of the adjustment member 49 is provided on a side of the adjustment member 49 opposite to a contact surface of the adjustment member 49, the contact surface contacting the vibration plane 25 of the ultrasonic transducer 13. The component material of the adjustment member 49 may be any material that is different from the material of the bumper 3, the housing 15, and the color film 47. Also, a shape and thickness of the adjustment member 49 is not limited. Note that, in the present embodiment, in consideration of the design and the assemblability, as shown in FIG. 5, the adjustment member 49 has a circular shape on a plane that is parallel with the bumper 3. For example, the adjustment member 49 has a circular cross section taken along the plane parallel with the bumper 3. Specifically, the circular shape of the adjustment member 49 is similar to the shape of the through hole 9 and is relatively smaller than the circular shape of the through hole 9 as shown in FIG. 5.

When a temperature change in Young's modulus of elasticity (i.e., change in Young's modulus of elasticity due to a temperature change in the usage condition) is larger, a propagation state of vibration is changed in the transmission path of the ultrasonic vibration, and therefore errors in sensitivity or directivity becomes larger. In the present embodiment, the adjustment member 49 is made of a material having a smaller change in Young's modulus of elasticity due to temperature than a material that forms the bumper. For example, Young's modulus of elasticity of the material of the adjustment member 49 changes less than Young's modulus of elasticity of the material of the bumper 3 when the temperature changes. Specifically, the bumper 3 is made of polypropylene (PP), the housing 15 is made of aluminum (Al), and the color film 47 is made of coating film described in first embodiment. In relation to the above configuration, the adjustment member 49 is made of polycarbonate (PC) that has a smaller change in Young's modulus of elasticity due to temperature than PP. Therefore, errors in the sensitivity and the directivity due to the temperature change of the usage condition can be effectively limited even though the structure includes the adjustment member 49 as the transmission path of the ultrasonic vibration.

Note that, the mount structure for the sensor device 11 shown in the present embodiment (FIG. 4) may be formed in the following procedure, for example. Firstly, there is prepared the sensor device 11 that has the adjustment member 49 attached with the vibration plane 25 of the ultrasonic transducer 13. The sensor device 11 is mounted on the bumper 3 such that an opposite surface of the adjustment member 49 is generally flush with the outer surface 5 of the bumper 3. The opposite surface of the adjustment member 49 is provided on a side of the adjustment member 49 opposite to the bonding surface of the adjustment member 49 that is bonded with the vibration plane 25. Also, the color film 47 is attached to the entire surface of the outer surface 5 of the bumper 3 such that the mount structure for the sensor device 11 is made as shown in FIG. 4. In other words, the adjustment member 49 serves as a part of the sensor device 11. Note that, alternatively to the above, after the color film 47 is attached to the entire surface of the outer surface 5 of the bumper 3, the sensor device 11 having the adjustment member 49 may be mounted on the bumper 3. The above alternative method can also bring the similar structure.

As above, in the mount structure of the sensor device 11 according to the present embodiment, a component material and a thickness of the adjustment member 49 can be set as necessary as above. As a result, in addition to the advantages described in the first embodiment, the sensing property can be more flexibly adjusted. As a result, as described in the present embodiment, the sensing property can be improved depending on the design.

Note that, the present embodiment describes an example, where the adjustment member 49 is made of the material having a smaller change in Young's modulus of elasticity due to temperature than the component material of the bumper 3. However, as above, any alternative component material may be employed provided that the material is other than materials that form the bumper 3, the housing 15, and the color film 47. For example, as described in the present embodiment, in the sensor device 11 that has the piezoelectric element 17, and that transmits and receives ultrasonic wave, the adjustment member 49 may have an acoustic impedance that falls between an acoustic impedance of the color film 47 and an acoustic impedance of the housing 15 (the bottom surface portion 21). The above configuration reduces the reflection of the ultrasonic wave at the boundary surface between the housing 15 and the adjustment member 49. Also, the configuration reduces the reflection at the boundary surface between the adjustment member 49 and the color film 47, and thereby the sensitivity can be improved.

Also, the present embodiment describes an example, where the adjustment member 49 has the shape that is similar to the shape of the through hole 9, and the adjustment member 49 has a cross-section having a circular shape slightly smaller than a circular shape of the through hole 9. However, as above, the shape and the thickness of the adjustment member 49 are not limited to anything particular. For example, in the sensor device 11 that has the piezoelectric element 17, and that receives and transmits the ultrasonic waves, the adjustment member 49 that is provided between the piezoelectric element 17 and the color film 47 narrows the vibration range such that the directivity can be adjusted. For example, as shown in FIG. 6, the shape of the adjustment member 49 may be a rectangle that has a first side perpendicular to the ground and a second side horizontal to the ground. The first side of the rectangle is longer than the second side. In the above configuration, the directivity becomes wider in the horizontal direction than in the vertical direction. Note that, as shown in FIG. 6, when the through hole 9 also has a shape that matches with the shape of the adjustment member 49, a gap between the adjustment member 49 and the bumper 3 is made smaller, and thereby the color film 47 is limited to have a projection and recess, or the design can be improved.

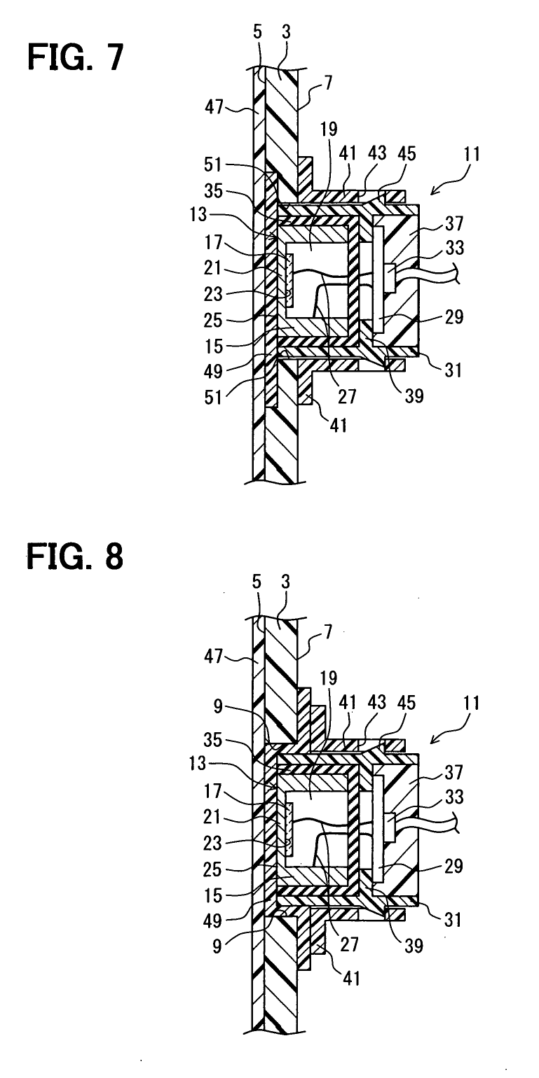

Note that, the present embodiment describes an example, in which the adjustment member 49 is attached to the vibration plane 25 of the ultrasonic transducer 13 before the adjustment member 49 is mounted on the bumper 3. However, the sensor device 11 other than the adjustment member 49 may be alternatively mounted on the bumper 3 in a state, the adjustment member 49 is fixed to the bumper 3. For example, as shown in FIG. 7, a through hole 51 may be alternatively provided to the bumper 3 in place of the through hole 9. The through hole 51 has a step that defines a larger diameter portion on the outer surface 5 side of the through hole 51 larger than a diameter of the through hole 51 on the inner surface 7 side thereof. the adjustment member 49 that constitutes the sensor device 11 is in advance fixed to the through hole 51 of the bumper 3. Then, after the fixation of the adjustment member 49, the sensor device 11 except for the adjustment member 49 is adhered to the bumper 3 such that the vibration plane 25 of the ultrasonic transducer 13 contacts the adjustment member 49.

Note that the present embodiment describes an example, in which the entire of the adjustment member 49 is provided inside the through hole 9. However, the adjustment member 49 may at least have a portion that is received by the through hole 9 (the through hole 51), alternatively. For example, as shown in FIG. 8, the adjustment member 49 has a projection portion that projects from the inner surface 7 of the bumper 3 toward the inside of the vehicle. In the above configuration, the adjustment member 49 is in advance fixed to the bumper 3, and then, the sensor device 11 except for the adjustment member 49 may be mounted to the bumper 3. Alternatively, after the adjustment member 49 is adhered to the vibration plane 25 of the ultrasonic transducer 13, the sensor device 11 may be mounted to the bumper 3. Note that in FIG. 8, in a state, where the projection portion of the adjustment member 49 that projects from the inner surface 7 of the bumper 3 toward the inside of the vehicle is fixed to the inner surface 7 of the bumper 3, the sensor device 11 except for the adjustment member 49 is mounted to the bumper 3. In FIG. 8, the holder 41 is fixed to the adjustment member 49. However, the adjustment member 49 may alternatively have a partial cut that is used to be fixed to the inner surface 7 of the bumper 3.

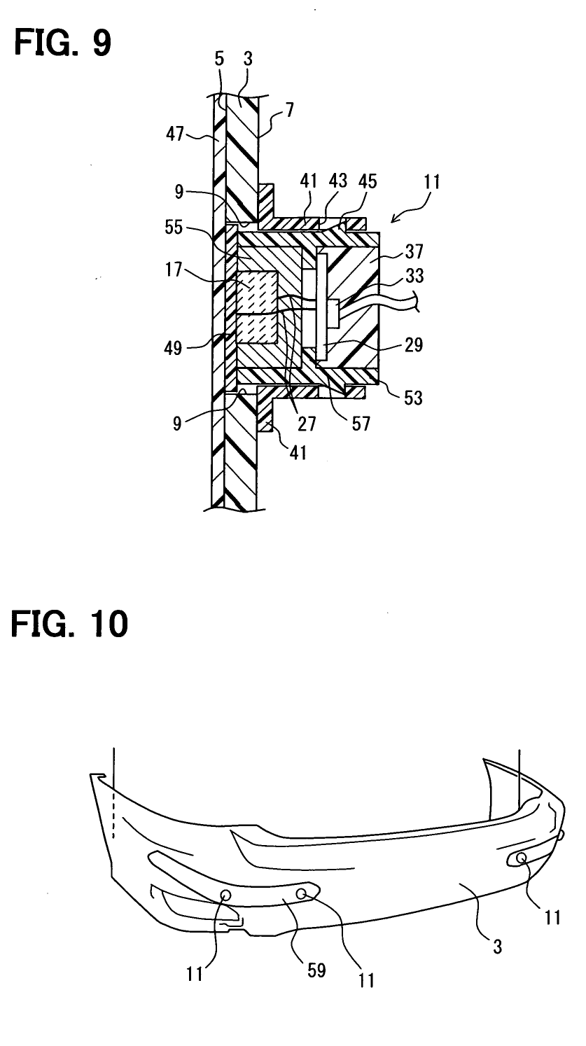

The present embodiment describes an example, in which the ultrasonic transducer 13 has the piezoelectric element 17 that is fixed to the inner surface 23 of the bottom surface portion 21 of the housing 15, and in which the ultrasonic wave is transmitted between the piezoelectric element 17 and the exterior of the vehicle through the color film 47, the adjustment member 49, and the bottom surface portion 21 of the housing 15. However, for example, as shown in FIG. 9, the piezoelectric element 17 may directly contact the adjustment member 49 alternatively. In the configuration, the ultrasonic wave is transmitted between the piezoelectric element 17 and the vehicle through the color film 47 and the adjustment member 49. As a result, in addition to the above advantages of the adjustment member 49, the sensitivity can be more improved compared with the previously described configuration of the above embodiments and modifications. Note that in FIG. 9, a tubular case 53 receives the piezoelectric element 17. Also, a vibration control member 55 limits unwanted vibration from the piezoelectric element 17 to the case 53, and is mounted on the piezoelectric element 17 for fixing the piezoelectric element 17 inside the case 53. The vibration control member 55 is, for example, made of a silicone rubber. A stopper 57 fixes the piezoelectric element 17 that is covered by the vibration control member 55 and the circuit board 29 in the tubular case 53. Note that the piezoelectric element 17 is received by the case 53 through one opening of the case 53, and the circuit board 29 is received by the case 53 through another opening of the case 53. Note that in the configuration, the case 53 corresponds to an enclosure in the present invention. FIG. 9 is a cross-sectional view showing a modified embodiment. Here, in the configuration shown in FIG. 9, the case 53 has a tubular shape having a bottom, and an inner surface of the bottom surface portion is fixed to the piezoelectric element 17. As a result, the ultrasonic wave may be transmitted to the exterior of the vehicle through the color film 47, the adjustment member 49, and the bottom surface portion of the case 53.

Preferred embodiments of the present invention are described above. However, the present invention is not limited to the above embodiments, but the present invention can be practiced in various modifications provided that the gist of the present invention is not deviated.

In the present embodiment, an example of the vehicle that serves as a mobile unit is described. However, the present invention can be applied to a mobile unit other than the vehicle. Also, the bumper of the vehicle is described as a wall member, but the wall member is not limited to the bumper. The wall member may be alternatively a body (metal thin plate) of the vehicle, or a resin-made molding that is provided to a portion of the bumper or the body. For example, as shown in FIG. 10, the mount structure of the present invention may be applied for mounting the sensor devices 11 on a bumper molding 59, which is provided at each corner of the bumper 3 as shown in the present embodiment. In the alternative configuration, the similar advantages can be obtained.

In the present embodiment, the sensor device includes the housing, which serves as an enclosure, the vibration control member, the circuit board, and the case, in addition to the piezoelectric element that serves as a sensing element. However, the sensor device may alternatively have other configuration provided that the sensor device includes at least the sensing element. For example, the alternative sensor device may have the piezoelectric element 17 that is adhered with the adjustment member 49.

In the present embodiment, the sensor device is the ultrasonic wave sensor device that has the piezoelectric element serving as the ultrasonic element. However, the sensor device is not limited to the above example. For example, the mount structure of the present invention may be alternatively applied to a collision sensor device that has the piezoelectric element. Then, the similar advantages can be obtained. Also, the sensing element is not limited to the piezoelectric element.

Note that in the present embodiment, the color film is applied to the structure, which has the sensor device and the wall member having the through hole, the sensor device being mounted on the wall member. However, the wall member may alternatively be provided integrally with the adjustment member, which is positioned correspondingly to the mounting position of the sensor device. In other words, the adjustment member is embedded in the wall member as a portion of the wall member. Then, the sensor device is mounted on the above wall member at a position such that the sensor device contacts the adjustment member. If the color film described in the present invention is applied to the above alternative configuration (if the color film is adhered to the outer surface entire surface of the wall member of the alternative configuration), the similar advantages similar to those in the above embodiments of the present invention can be obtained.

Additional advantages and modifications will readily occur to those skilled in the art. The invention in its broader terms is therefore not limited to the specific details, representative apparatus, and illustrative examples shown and described.

What is claimed is:

1. A mount structure for a mobile unit comprising:
a wall member that is provided to the mobile unit, the wall member having a through hole and an outer surface;
a sensor device that is mounted on the wall member via the through hole such that a sensing element of the sensor device is able to perform sensing, the sensor device being coupled to the wall member in a state, where the sensor device has a portion that is generally flush with the outer surface of the wall member, and that is provided inside the through hole; and
a color film that is adhered to an entire surface of the outer surface of the wall member, the entire surface having an opening of the through hole, the sensor device contacting the color film.

2. The mount structure according to claim 1, wherein:
the sensor device has an enclosure that receives the sensing element therein, and that has a coupling surface that is coupled to the sensing element; and
the enclosure has an opposite surface on a side of the enclosure opposite to the coupling surface, the opposite surface contacting the color film.

3. The mount structure according to claim 2, wherein:
the sensing element includes an ultrasonic element that converts an electrical signal into an ultrasonic vibration, and that converts the ultrasonic vibration into the electrical signal;
the enclosure has a bottom surface portion that has an inner surface, the sensing element contacting and being coupled to the inner surface of the bottom surface portion in a state, where the sensing element is received by the enclosure, the inner surface of the bottom surface portion serving as the coupling surface of the enclosure; and
the bottom surface portion of the enclosure has an outer surface that contacts the color film, the outer surface of the bottom surface portion serving as the opposite surface of the enclosure.

4. The mount structure according to claim 1, further comprising:
an adjustment member that is made of a material that is different from materials of the wall member and the color film, wherein:
the adjustment member has a contacting surface that contacts the sensor device;
the adjustment member has an opposite surface on a side of the adjustment member opposite to the contact surface, the opposite surface of the adjustment member being generally flush with the outer surface of the wall member in a state, where the adjustment member is coupled to the sensor device; and
the adjustment member contacts the color film.

5. The mount structure according to claim 4, wherein:
the sensor device includes an enclosure that receives the sensing element, and that is coupled to the sensing element;
the adjustment member is made of a material different from materials of the wall member, the color film, and the enclosure;
the contact surface of the adjustment member contacts at least one of the enclosure and the sensing element;
the opposite surface of the adjustment member being generally flush with the outer surface of the wall member in a state, where the adjustment member is coupled to the sensor device.

6. The mount structure according to claim 5, wherein:
the sensing element includes an ultrasonic element that converts an electrical signal into an ultrasonic vibration, and that converts the ultrasonic vibration into the electrical signal; and
the ultrasonic element contacts the adjustment member.

7. The mount structure according to claim 5, wherein:
the sensing element includes an ultrasonic element that converts an electrical signal into an ultrasonic vibration, and that converts the ultrasonic vibration into the electrical signal;
the enclosure has a bottom surface portion that has an inner surface, the sensing element contacting and being coupled to the inner surface of the bottom surface portion in a state, where the sensing element is received by the enclosure; and
the bottom surface portion of the enclosure has an outer surface that contacts the adjustment member.

8. The mount structure according to claim 4, wherein:
the adjustment member is made of a material having a smaller temperature change in Young's modulus of elasticity than a material of the wall member.

9. The mount structure according to claim 7, wherein:
the adjustment member has an acoustic impedance that falls between (a) an acoustic impedance of the color film and (b) an acoustic impedance of the bottom surface portion of the enclosure.

10. The mount structure according to claim 1, wherein:
the sensor device has a processing circuit for the sensing element.

11. The mount structure according to claim 1, wherein:
the mobile unit is a vehicle; and
the wall member is at least one of a bumper, a bumper molding, and a body of the vehicle.

12. The mount structure according to claim 1, wherein:
the outer surface of the wall member faces outwardly to an exterior of the mobile unit.

13. A mount structure for a mobile unit comprising:
a sensor device that is mounted on a wall member of the mobile unit via a through hole of the wall member such that a sensing element of the sensor device is able to perform sensing, the sensor device being coupled to the wall member in a state, where the sensor device has a portion that is generally flush with an outer surface of the wall member, and that is provided inside the through hole; and
a color film that is adhered to an entire surface of the outer surface of the wall member, the entire surface having an opening of the through hole, the sensor device contacting the color film.

14. The mount structure according to claim 13 further comprising:
an adjustment member that is made of a material that is different from materials of the wall member and the color film, wherein:
the adjustment member has a contacting surface that contacts the sensor device;
the adjustment member has an opposite surface on a side of the adjustment member opposite to the contact surface, the opposite surface of the adjustment member being generally flush with the outer surface of the wall member in a state, where the adjustment member is coupled to the sensor device; and
the adjustment member contacts the color film.

15. The mount structure according to claim 14, wherein:
the adjustment member is made of a material having a smaller temperature change in Young's modulus of elasticity than a material of the wall member.
